(19) United States
(12) Patent Application Publication
(10) Pub. No.: US 2018/0287560 A1
(43) Pub. Date: Oct. 4, 2018

(54) DUAL OPERATING MODE POWER AMPLIFYING APPARATUS

(71) Applicant: SAMSUNG ELECTRO-MECHANICS CO., LTD., Suwon-si (KR)

(72) Inventor: Jae Hyouck CHOI, Suwon-si (KR)

(73) Assignee: SAMSUNG ELECTRO-MECHANICS CO., LTD., Suwon-si (KR)

(21) Appl. No.: 15/795,620

(22) Filed: Oct. 27, 2017

(30) Foreign Application Priority Data
Mar. 31, 2017 (KR) 10-2017-0041601

(51) Int. Cl. H03F 1/02

(52) U.S. Cl. CPC H03F 1/02

(57) ABSTRACT

A dual operating mode power amplifying apparatus, includes a power amplifying circuit configured to comprise a unit amplifier amplifying an input signal; a first bias circuit configured to generate a first bias current of the power amplifying circuit; a second bias circuit configured to generate a second bias current of the power amplifying circuit, the second bias current being a signal independent of the first bias current; a first ballast circuit connected between the first bias circuit and the power amplifying circuit, and configured to transfer the first bias current to the power amplifying circuit; and a second ballast circuit connected between the second bias circuit and the power amplifying circuit, and configured to transfer the second bias current to the power amplifying circuit.

### CROSS-REFERENCE TO RELATED APPLICATION(S)

This application claims benefit under 35 USC 119(a) of Korean Patent Application No. 10-2017-0041601 filed on Mar. 31, 2017 in the Korean Intellectual Property Office, the entire disclosure of which is incorporated herein by reference for all purposes.

### BACKGROUND

### 1. Field

The following description relates to a dual operating mode power amplifying apparatus for use in a mobile device.

### 2. Description of Related Art

In general, in accordance with the development of wireless communications technology, 3^{rd} generation (3G) mobile communications and 4^{th} generation (4G) mobile communications, such as long term evolution (LTE), or the like, have been used. Data usage has increased in accordance with an increase in 4G mobile communications networks, such that amounts of current consumed in mobile devices such as cellular phones have increased. Therefore, research into a method of reducing a consumed current has been gradually conducted.

Generally, mobile devices such as cellular phones include a power amplifying apparatus amplifying power of a transmission signal.

The power amplifying apparatus may be operated in a high-power operating mode or a low-power operating mode by including a plurality of unit amplifiers and high-power and low-power bias circuits driving the unit amplifiers.

The plurality of unit amplifiers receive bias currents from each of the high-power bias circuit and the low-power bias circuit through one segment ballast resistor.

The segment ballast resistor may have an influence on adjacent channel leakage ratio (ACLR) performance of the power amplifying apparatus and improve isolation between the plurality of unit amplifiers to alleviate a loop that may be generated between the plurality of unit amplifiers.

However, since the existing power amplifying apparatus is operated through one segment ballast resistor in each of the high-power operating mode and the low-power operating mode, the existing power amplifying apparatus may not provide a state optimal for each of the high-power operating mode and the low-power operating mode.

That is, the existing power amplifying apparatus includes one segment ballast resistor connected in common to the plurality of unit amplifiers, such that the plurality of unit amplifiers, the high-power bias circuit and the low-power bias circuit have an influence on each other in each of the high-power operating mode and the low-power operating mode. Therefore, there is a need to improve the isolation.

As an example, in a case in which the existing power amplifying apparatus is designed to be appropriate for the high-power operating mode, when the existing power amplifying apparatus is operated in the low-power operating mode, the ACLR performance is deteriorated.

Therefore, a current is further consumed in order to improve the ACLR performance in the low-power operating mode.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a dual operating mode power amplifying apparatus, includes a power amplifying circuit configured to comprise a unit amplifier amplifying an input signal; a first bias circuit configured to generate a first bias current of the power amplifying circuit; a second bias circuit configured to generate a second bias current of the power amplifying circuit, the second bias current being a signal independent of the first bias current; a first ballast circuit connected between the first bias circuit and the power amplifying circuit, and configured to transfer the first bias current to the power amplifying circuit; and a second ballast circuit connected between the second bias circuit and the power amplifying circuit, and configured to transfer the second bias current to the power amplifying circuit.

The first ballast circuit may be configured to include a first high-power ballast resistor and the second ballast circuit is configured to comprise a first low-power ballast resistor.

The first bias circuit may include a first current source, a first drain resistor, first and second transistors having a diode connection, and a first ground resistor connected to each other in series between a first operation voltage terminal and a ground; a third transistor connected to the first transistor in a current mirror structure; and a first capacitor connected between a gate of the third transistor and a ground.

The second bias circuit includes a second current source, a second drain resistor, and fourth and fifth transistors having a diode connection, connected to each other in series between a second operation voltage terminal and a ground; a sixth transistor connected to the fourth transistor in a current mirror structure; and a second capacitor connected between a gate of the sixth transistor and a ground.

The first ballast circuit may have a first resistance value set to isolate the first bias circuit and the second bias circuit each from the other during a high-power operating mode of the dual operating mode power amplifying apparatus.

The second ballast circuit may have a second resistance value set to isolate the first bias circuit and the second bias circuit each from the other during a low-power operating mode of the dual operating mode power amplifying apparatus.

The first ballast circuit may have a first resistance value configured to maintain an adjacent channel leakage ratio (ACLR) of the power amplifying circuit at a specific level during a high-power operating mode of the dual operating mode power amplifying apparatus.

The second ballast circuit may have a second resistance value configured to maintain an adjacent channel leakage ratio (ACLR) of the power amplifying circuit at a specific level during a low-power operating mode of the dual operating mode power amplifying apparatus.

The first ballast circuit may adjust an amount of the first bias current between the first bias circuit and the power amplifying circuit during a high-power operating mode of the dual operating mode power amplifying apparatus, and the second ballast circuit may adjust an amount of the second bias current between the second bias circuit and the power amplifying circuit during a low-power operating mode of the dual operating mode power amplifying apparatus.

In another general aspect, a dual operating mode power amplifying apparatus includes: a power amplifying circuit configured to comprise unit amplifiers each configured to amplify an input signal, wherein each of the unit amplifiers is connected to another in parallel; a first bias circuit configured to generate a first bias current of the power amplifying circuit; a second bias circuit configured to generate a second bias current of the power amplifying circuit, the second bias current being a signal independent of the first bias current; a first ballast circuit comprising high-power ballast resistors each connected between the first bias circuit and the unit amplifiers, and configured to transfer the first bias current to each of the unit amplifiers through each of the high-power ballast resistors; and a second ballast circuit comprising low-power ballast resistors each connected between the second bias circuit and the unit amplifiers, and configured to transfer the second bias current to each of the unit amplifiers through each of the low-power ballast resistors.

The first bias circuit may include: a first current source, a first drain resistor, first and second transistors having a diode connection, and a first ground resistor connected to each other in series between a first operation voltage terminal and a ground; a third transistor connected to the first transistor in a current mirror structure; and a first capacitor connected between a gate of the third transistor and a ground.

The second bias circuit may include: a second current source, a second drain resistor, and fourth and fifth transistors having a diode connection, connected to each other in series between a second operation voltage terminal and a ground; a sixth transistor connected to the fourth transistor in a current mirror structure; and a second capacitor connected between a gate of the sixth transistor and a ground.

The first ballast circuit and the second ballast circuit may have respective resistance values set to isolate the unit amplifiers each from the other during a high-power operating mode of the dual operating mode power amplifying apparatus.

The first ballast circuit and the second ballast circuit may have respective resistance values set to isolate the first bias circuit and the second bias circuit each from the other during a low-power operating mode of the dual operating mode power amplifying apparatus.

The first ballast circuit may have a first resistance value configured to maintain an adjacent channel leakage ratio (ACLR) of the power amplifying circuit at a specific level during a high-power operating mode of the dual operating mode power amplifying apparatus.

The second ballast circuit may have a second resistance value configured to maintain an adjacent channel leakage ratio (ACLR) of the power amplifying circuit at a specific level during a low-power operating mode of the dual operating mode power amplifying apparatus.

The first ballast circuit may adjust an amount of the first bias current between the first bias circuit and the power amplifying circuit during a high-power operating mode of the dual operating mode power amplifying apparatus, and the second ballast circuit may adjust an amount of the second bias current between the second bias circuit and the power amplifying circuit during a low-power operating mode of the dual operating mode power amplifying apparatus.

In another general aspect, a dual operating mode power amplifying apparatus, includes: a power amplifier configured to amplify an input signal; a first bias circuit configured to generate a first bias current of the power amplifier; a second bias circuit configured to generate a second bias current of the power amplifier, the second bias current being a signal independent of the first bias current; a first ballast circuit connected between the first bias circuit and the power amplifier, and configured to transfer the first bias current to the power amplifier in a first mode; and a second ballast circuit connected between the second bias circuit and the power amplifier, and configured to transfer the second bias current to the power amplifier in a second mode.

The first and second ballast circuits comprise a resistor.

Other features and aspects will be apparent from the following detailed description, the drawings, and the claims.

### BRIEF DESCRIPTION OF DRAWINGS

FIG. 1 is a block diagram illustrating an example of a dual operating mode power amplifying apparatus.

FIG. 2 is a block diagram illustrating another example of a dual operating mode power amplifying apparatus.

FIG. 3 is a circuit diagram illustrating an example of first and second bias circuits.

FIG. 4 is a graph illustrating an adjacent channel leakage ratio (ACLR) in a low-power operating mode of the dual operating mode power amplifying apparatus.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or wafer (substrate), is described as being “on,” “connected to,” or “coupled to” another element, it can be directly “on,” “connected to,” or “coupled to” the other element, or there may be other elements intervening therebetween. In contrast, when an element is referred to as being “directly on,” “directly connected to,” or “directly coupled to” another element, there can be no other elements or layers intervening therebetween. As used herein, the term “and/or” includes any and all combinations of one or more of the associated listed items.

Although terms such as “first,” “second,” and “third” maybe used herein to describe various members, components, regions, layers, and/or sections, these members, components, regions, layers, and/or sections are not to be limited by these terms. Rather, these terms are only used to distinguish one member, component, region, layer, or section from another member, component, region, layer, or section. Thus, a first member, component, region, layer, or section referred to in an example below could also be referred to as a second member, component, region, layer, or section without departing from the teachings of the example.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, Variations of the shapes shown in the drawings maybe occur. Thus, the examples described below are not to be construed as being limited to the particular shapes of regions shown in the drawings, but include changes in shape occurring during manufacturing.

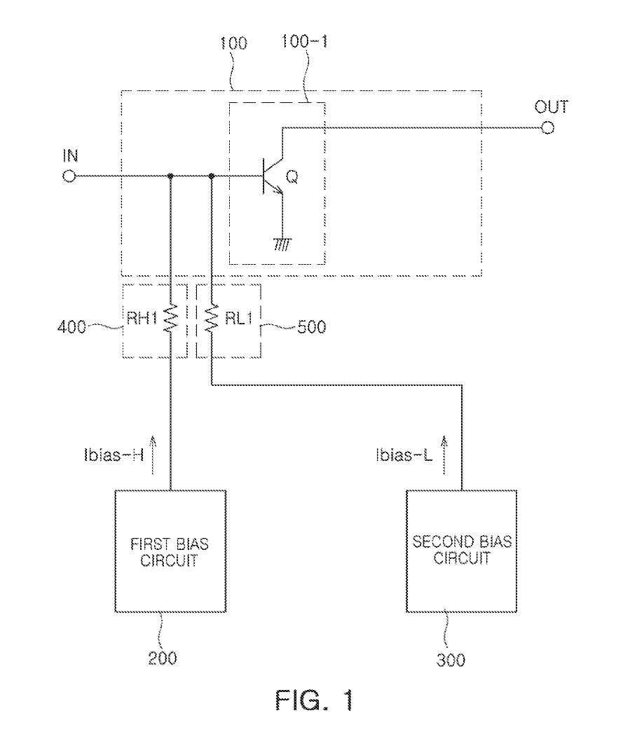

FIG. 1 is a block diagram illustrating an example of a dual operating mode power amplifying apparatus in the present disclosure.

Referring to FIG. 1, the dual operating mode power amplifying apparatus in the present disclosure includes a power amplifying circuit 100, a first bias circuit 200, a second bias circuit 300, a first ballast circuit 400, and a second ballast circuit 500.

The first ballast circuit 400 and the second ballast circuit 500 are devices placed in line between the first bias circuit 200 and the power amplifying circuit 100 or the second bias circuit 300 and the power amplifying circuit 100 to limit the amount of current flowing to the power amplifying circuit 100. The first ballast circuit 400 and/or the second ballast circuit 500 may be any one or any combination of any two or more of a fixed resistor, a variable resistor, an inductor, and a capacitor.

The power amplifying circuit 100 includes a unit amplifier 100-1. The unit amplifier 100-1 amplifies an input signal input through an input terminal IN and output the amplified signal through an output terminal OUT.

For example, the unit amplifier 100-1 includes at least one amplifying transistor such as a bipolar junction transistor (BJT), a hetero-junction bipolar transistor (HBT), and a metal oxide silicon field effect transistor (MOSFET).

The first bias circuit 200 generates a first bias current Ibias-H that is to be provided to the power amplifying circuit 100, in a high-power operating mode.

The second bias circuit 300 generates a second bias current Ibias-L that is to be provided to the power amplifying circuit 100, in a low-power operating mode. Here, the second bias current Ibias-L, which is a signal independent of the first bias current Ibias-H, is different from the first bias current Ibias-H.

The first ballast circuit 400 includes a first high-power ballast resistor RH1. The first high-power ballast resistor RH1 is connected between the first bias circuit 200 and the power amplifying circuit 100 to transfer the first bias current Ibias-H to the power amplifying circuit 100.

The second ballast circuit 500 includes a first low-power ballast resistor RL1. The first low-power ballast resistor RL1 is connected between the second bias circuit 300 and the power amplifying circuit 100 to transfer the second bias current Ibias-L to the power amplifying circuit 100.

Referring to FIG. 1, the first high-power ballast resistor RH1 of the first ballast circuit 400 is set to have a first resistance value, and performs an isolation function between the first bias circuit 200 and the second bias circuit 300 during the high-power operating mode of the dual operating mode power amplifying apparatus.

In addition, the first high-power ballast resistor RH1 of the first ballast circuit 400 maintains an adjacent channel leakage ratio (ACLR) of the power amplifying circuit 100 at a specific level during the high-power operating mode of the dual operating mode power amplifying apparatus.

Further, the first high-power ballast resistor RH1 of the first ballast circuit 400 adjusts an amount of the first bias current Ibias-H between the first bias circuit 200 and the power amplifying circuit 100 during the high-power operating mode of the dual operating mode power amplifying apparatus.

The first low-power ballast resistor RL1 of the second ballast circuit 500 is set to have a second resistance value different from the first resistance value, and performs an isolation function between the first bias circuit 200 and the second bias circuit 300 during the low-power operating mode of the dual operating mode power amplifying apparatus.

In addition, the first low-power ballast resistor RL1 of the second ballast circuit 500 maintain an ACLR of the power amplifying circuit 100 at a specific level during the low-power operating mode of the dual operating mode power amplifying apparatus.

Further, the first low-power ballast resistor RL1 of the second ballast circuit 500 adjusts the amount of the second bias current Ibias-L between the second bias circuit 300 and the power amplifying circuit 100 during the low-power operating mode of the dual operating mode power amplifying apparatus.

In the example described above, the first resistance value of the first ballast circuit 400 is a value corresponding to a state optimal for the high-power operating mode, the second resistance value of the second ballast circuit 500 is a value corresponding to a state optimal for the low-power operating mode, and the first resistance value and the second resistance value are different from each other.

In the respective drawings in the present disclosure, an unnecessary overlapping description for components denoted by the same reference numerals and having the same functions will be omitted, and contents different from each other will be described in the respective drawings.

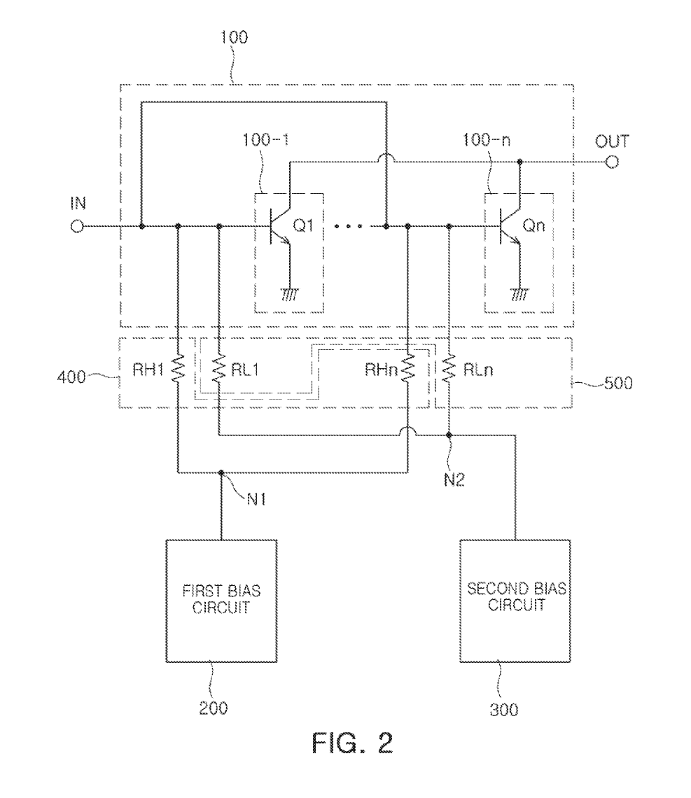

FIG. 2 is a block diagram illustrating another example of a dual operating mode power amplifying apparatus in the present disclosure.

Referring to FIG. 2, the dual operating mode power amplifying apparatus in the present disclosure includes a power amplifying circuit 100, a first bias circuit 200, a second bias circuit 300, a first ballast circuit 400, and a second ballast circuit 500.

The power amplifying circuit 100 includes a plurality of first to n-th unit amplifiers 100-1 to 100-n (n is a natural number that is at least 2) connected to one another in parallel when required power may not be satisfied by one unit amplifier.

In this case, each of the first to n-th unit amplifiers 100-1 to 100-n amplifies an input signal input through an input terminal IN and output the amplified signal through an output terminal OUT.

The first bias circuit 200 generates a first bias current Ibias-H that is to be provided to the power amplifying circuit 100 and provides the first bias current Ibias-H to the first ballast circuit 400 through a first connection node N1, in a high-power operating mode.

The second bias circuit 300 generates a second bias current Ibias-L that is to be provided to the power amplifying circuit 100 and provides the second bias current Ibias-L to the second ballast circuit 500 through a second connection node N2, in a low-power operating mode. Here, the second bias current Ibias-L, which is a signal independent of the first bias current Ibias-H, is different from the first bias current Ibias-H.

The first ballast circuit 400 includes first to n-th high-power ballast resistors RH1 to RHn.

The first to n-th high-power ballast resistors RH1 to RHn are connected between the first bias circuit 200 and the first to n-th unit amplifiers 100-1 to 100-n, respectively, and transfer the first bias current Ibias-H to the first to n-th unit amplifiers 100-1 to 100-n, respectively.

The second ballast circuit 500 includes first to n-th low-power ballast resistors RL1 to RLn.

The first to n-th low-power ballast resistors RL1 to RLn are connected between the second bias circuit 300 and the first to n-th unit amplifiers 100-1 to 100-n, respectively, and transfer the second bias current Ibias-L to the first to n-th unit amplifiers 100-1 to 100-n, respectively.

Each of the first to n-th high-power ballast resistors RH1 to RHn of the first ballast circuit 400 is set to have a first resistance value, and performs an isolation function between the first bias circuit 200 and the second bias circuit 300 during the high-power operating mode of the dual operating mode power amplifying apparatus and performs an isolation function between the first to n-th unit amplifiers 100-1 to 100-n.

In addition, each of the first to n-th high-power ballast resistors RH1 to RHn of the first ballast circuit 400 maintains an ACLR of the power amplifying circuit 100 at a specific level during the high-power operating mode of the dual operating mode power amplifying apparatus.

Further, each of the first to n-th high-power ballast resistors RH1 to RHn of the first ballast circuit 400 adjusts an amount of the first bias current Ibias-H between the first bias circuit 200 and the power amplifying circuit 100 during the high-power operating mode of the dual operating mode power amplifying apparatus.

Each of the first to n-th low-power ballast resistors RL1 to RLn of the second ballast circuit 500 is set to have a second resistance value, and performs an isolation function between the first bias circuit 200 and the second bias circuit 300 during the low-power operating mode of the dual operating mode power amplifying apparatus and perform isolation between the first to n-th unit amplifiers 100-1 to 100-n.

In addition, each of the first to n-th low-power ballast resistors RL1 to RLn of the second ballast circuit 500 maintains an ACLR of the power amplifying circuit 100 at a specific level during the low-power operating mode of the dual operating mode power amplifying apparatus.

Further, each of the first to n-th low-power ballast resistors RL1 to RLn of the second ballast circuit 500 adjusts an amount of the second bias current Ibias-L between the second bias circuit 300 and the power amplifying circuit 100 during the low-power operating mode of the dual operating mode power amplifying apparatus.

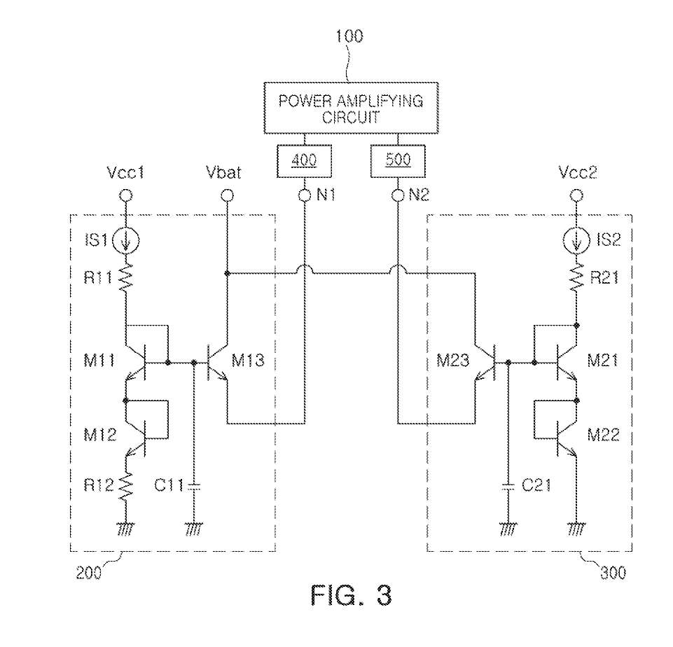

FIG. 3 is a circuit diagram illustrating an example of first and second bias circuits in the present disclosure.

Referring to FIG. 3, the first bias circuit 200 includes a first current source IS1, a first drain resistor R11, first and second transistors M11 and M12 having a diode connection, a first ground resistor R12, a third transistor M13, and a first capacitor C11.

As an example, the first current source IS1, the first drain resistor R11, the first and second transistors M11 and M12 having the diode connection, and the first ground resistor R12 are connected to each other in series between a first operation voltage Vcc1 terminal and a ground.

In this case, the first current source IS1 generates a first current that is preset, and allows the first current to flow through the first drain resistor R11, the first and second transistors M11 and M12 having the diode connection, and the first ground resistor R12.

The third transistor M13 is connected to the first transistor M11 in a current mirror structure. Therefore, the third transistor M13 mirrors the first current to the first bias current depending on a size ratio between the third transistor M13 and the first transistor M11, and provide the first bias current to the first ballast circuit 400.

Here, the first capacitor C11 is connected between a gate of the third transistor M13 and a ground to stabilize a gate voltage of the third transistor M13.

Next, the second bias circuit 300 include a second current source IS2, a second drain resistor R21, fourth and fifth transistors M21 and M22 having a diode connection, a sixth transistor M23, and a second capacitor C21.

The second current source IS2, the second drain resistor R21, and the fourth and fifth transistors M21 and M22 having the diode connection are connected to each other in series between a second operation voltage Vcc2 terminal and a ground.

In this case, the second current source IS1 generates a second current that is preset. The second current source IS1 allows the second current to flow through the second drain resistor R21, the fourth and fifth transistors M21 and M22 having the diode connection, and the second ground resistor R22.

The sixth transistor M23 is connected to the fourth transistor M21 in a current mirror structure. Therefore, the sixth transistor M23 mirrors the second current to the second bias current depending on a size ratio between the sixth transistor M23 and the fourth transistor M21, and provides the second bias current to the second ballast circuit 500.

Here, the second capacitor C21 is connected between a gate of the sixth transistor M23 and a ground to stabilize a gate voltage of the sixth transistor M23.

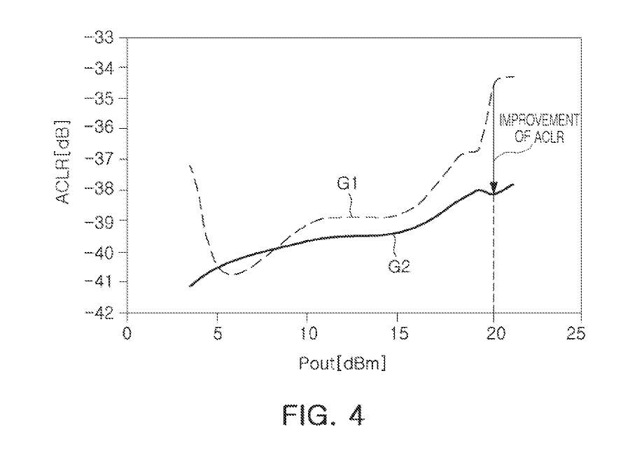

FIG. 4 is a graph illustrating an ACLR in a low-power operating mode of the dual operating mode power amplifying apparatus in the present disclosure.

In FIG. 4, G1 is a graph illustrating an ACLR in a low-power operating mode in a power amplifying apparatus according to the related art, and G2 is a graph illustrating an ACLR in a low-power operating mode of the dual operating mode power amplifying apparatus according to the examples in the present disclosure.

When comparing ACLRs in the low-power operating modes of the power amplifying apparatus according to the related art and the dual operating mode power amplifying apparatus according to the examples in the present disclosure with each other in output power of around 20[dBm] of G1 and G2, it is confirmed that the ACLR characteristics in the low-power operating mode of the dual operating mode power amplifying apparatus in the present disclosure are improved as compared to ACLR characteristics in the low-power operating mode of the power amplifying apparatus in the related art.

As set forth above, according to the examples in the present disclosure, segment ballast resistors having different values optimized for each of dual operating modes are connected to unit amplifiers, such that high-power and low-power bias circuits may be connected to the unit amplifiers through the resistors having the different values, resulting in improving isolation between the bias circuits and between the unit amplifiers and maintaining an ACLR at a predetermined level.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A dual operating mode power amplifying apparatus, comprising:
a power amplifying circuit configured to comprise a unit amplifier amplifying an input signal;
a first bias circuit configured to generate a first bias current of the power amplifying circuit;
a second bias circuit configured to generate a second bias current of the power amplifying circuit, the second bias current being a signal independent of the first bias current;
a first ballast circuit connected between the first bias circuit and the power amplifying circuit, and configured to transfer the first bias current to the power amplifying circuit; and
a second ballast circuit connected between the second bias circuit and the power amplifying circuit, and configured to transfer the second bias current to the power amplifying circuit.

2. The dual operating mode power amplifying apparatus of claim 1, wherein the first ballast circuit is configured to comprise a first high-power ballast resistor and the second ballast circuit is configured to comprise a first low-power ballast resistor.

3. The dual operating mode power amplifying apparatus of claim 2, wherein the first bias circuit comprises:
a first current source, a first drain resistor, first and second transistors having a diode connection, and a first ground resistor connected to each other in series between a first operation voltage terminal and a ground;
a third transistor connected to the first transistor in a current mirror structure; and
a first capacitor connected between a gate of the third transistor and a ground.

4. The dual operating mode power amplifying apparatus of claim 1, wherein the second bias circuit comprises:
a second current source, a second drain resistor, and fourth and fifth transistors having a diode connection, connected to each other in series between a second operation voltage terminal and a ground;
a sixth transistor connected to the fourth transistor in a current mirror structure; and
a second capacitor connected between a gate of the sixth transistor and a ground.

5. The dual operating mode power amplifying apparatus of claim 2, wherein the first ballast circuit has a first resistance value set to isolate the first bias circuit and the second bias circuit each from the other during a high-power operating mode of the dual operating mode power amplifying apparatus.

6. The dual operating mode power amplifying apparatus of claim 1, wherein the second ballast circuit has a second resistance value set to isolate the first bias circuit and the second bias circuit each from the other during a low-power operating mode of the dual operating mode power amplifying apparatus.

7. The dual operating mode power amplifying apparatus of claim 2, wherein the first ballast circuit has a first resistance value configured to maintain an adjacent channel leakage ratio (ACLR) of the power amplifying circuit at a specific level during a high-power operating mode of the dual operating mode power amplifying apparatus.

8. The dual operating mode power amplifying apparatus of claim 2, wherein the second ballast circuit has a second resistance value configured to maintain an adjacent channel leakage ratio (ACLR) of the power amplifying circuit at a specific level during a low-power operating mode of the dual operating mode power amplifying apparatus.

9. The dual operating mode power amplifying apparatus of claim 2, wherein the first ballast circuit adjusts an amount of the first bias current between the first bias circuit and the power amplifying circuit during a high-power operating mode of the dual operating mode power amplifying apparatus, and
the second ballast circuit adjusts an amount of the second bias current between the second bias circuit and the power amplifying circuit during a low-power operating mode of the dual operating mode power amplifying apparatus.

10. A dual operating mode power amplifying apparatus comprising:
a power amplifying circuit configured to comprise unit amplifiers each configured to amplify an input signal, wherein each of the unit amplifiers is connected to another in parallel;
a first bias circuit configured to generate a first bias current of the power amplifying circuit;
a second bias circuit configured to generate a second bias current of the power amplifying circuit, the second bias current being a signal independent of the first bias current;
a first ballast circuit comprising high-power ballast resistors each connected between the first bias circuit and the unit amplifiers, and configured to transfer the first bias current to each of the unit amplifiers through each of the high-power ballast resistors; and
a second ballast circuit comprising low-power ballast resistors each connected between the second bias circuit and the unit amplifiers, and configured to transfer the second bias current to each of the unit amplifiers through each of the low-power ballast resistors.

11. The dual operating mode power amplifying apparatus of claim 10, wherein the first bias circuit comprises:
a first current source, a first drain resistor, first and second transistors having a diode connection, and a first ground resistor connected to each other in series between a first operation voltage terminal and a ground;
a third transistor connected to the first transistor in a current mirror structure; and
a first capacitor connected between a gate of the third transistor and a ground.

12. The dual operating mode power amplifying apparatus of claim 10, wherein the second bias circuit comprises:
a second current source, a second drain resistor, and fourth and fifth transistors having a diode connection, connected to each other in series between a second operation voltage terminal and a ground;
a sixth transistor connected to the fourth transistor in a current mirror structure; and
a second capacitor connected between a gate of the sixth transistor and a ground.

13. The dual operating mode power amplifying apparatus of claim 10, wherein the first ballast circuit and the second ballast circuit have respective resistance values set to isolate the unit amplifiers each from the other during a high-power operating mode of the dual operating mode power amplifying apparatus.

14. The dual operating mode power amplifying apparatus of claim 10, wherein the first ballast circuit and the second ballast circuit have respective resistance values set to isolate the first bias circuit and the second bias circuit each from the other during a low-power operating mode of the dual operating mode power amplifying apparatus.

15. The dual operating mode power amplifying apparatus of claim 10, wherein the first ballast circuit has a first resistance value configured to maintain an adjacent channel leakage ratio (ACLR) of the power amplifying circuit at a specific level during a high-power operating mode of the dual operating mode power amplifying apparatus.

16. The dual operating mode power amplifying apparatus of claim 10, wherein the second ballast circuit has a second resistance value configured to maintain an adjacent channel leakage ratio (ACLR) of the power amplifying circuit at a specific level during a low-power operating mode of the dual operating mode power amplifying apparatus.

17. The dual operating mode power amplifying apparatus of claim 10, wherein the first ballast circuit adjusts an amount of the first bias current between the first bias circuit and the power amplifying circuit during a high-power operating mode of the dual operating mode power amplifying apparatus, and
the second ballast circuit adjusts an amount of the second bias current between the second bias circuit and the power amplifying circuit during a low-power operating mode of the dual operating mode power amplifying apparatus.

18. A dual operating mode power amplifying apparatus, comprising:
a power amplifier configured to amplify an input signal;
a first bias circuit configured to generate a first bias current of the power amplifier;
a second bias circuit configured to generate a second bias current of the power amplifier, the second bias current being a signal independent of the first bias current;
a first ballast circuit connected between the first bias circuit and the power amplifier, and configured to transfer the first bias current to the power amplifier in a first mode; and
a second ballast circuit connected between the second bias circuit and the power amplifier, and configured to transfer the second bias current to the power amplifier in a second mode.

19. The dual operating mode power amplifying apparatus of claim 18, wherein the first and second ballast circuits comprise a resistor.
